(19) United States
(12) Patent Application Publication
(10) Pub. No.: US 2026/0003244 A1
(43) Pub. Date: Jan. 1, 2026

(54) FIBER COUPLED RADICAL DETECTION

(71) Applicant: Applied Materials, Inc., Santa Clara, CA (US)

(72) Inventor: TIMOTHY CHEN, Los Altos, CA (US)

(21) Appl. No.: 18/759,478

(22) Filed: Jun. 28, 2024

(51) Int. Cl. G02F 1/355; G02F 1/377; G02F 1/39; H01S 5/00

(52) U.S. Cl. CPC G02F 1/3558; G02F 1/3775; G02F 1/39; H01S 5/0064; H01S 5/0092

(57) ABSTRACT

Embodiments described herein relate to an apparatus that includes a chamber, and a molecular radical detector coupled to the chamber. In an embodiment, the molecular radical detector includes a diode laser, and a periodically poled lithium niobate (PPLN) waveguide coupled to the diode laser by a first optical fiber. In an embodiment, a filter is optically coupled to the PPLN waveguide by a second optical fiber, and a detector is optically coupled to the filter. In an embodiment, the PPLN waveguide is configured to frequency double a beam originating from the diode laser before the beam passes through an optical port in the chamber. In an embodiment, the detector is configured to receive the beam after the beam passes through the chamber.

### BACKGROUND

### 1) Field

Embodiments of the present disclosure pertain to the field of molecular radical detection within a chamber using a narrow band fiber-coupled near-infrared (IR) laser and a periodically poled lithium niobate (PPLN) waveguide to double the frequency.

### 2) Description of Related Art

In semiconductor processing, on-line monitoring of radicals is a key measurement technique to maintain the health and performance of plasmas. Certain radicals have electronic absorption bands in the visible light spectrum. For example, NH₂ radicals exhibit an absorption band at 597.4 nm. However, narrow band diode lasers are not available at such wavelengths. Accordingly, existing solutions for providing radical monitoring include continuous wave dye lasers. Such lasers are bulky and require the use of toxic dyes (e.g., rhodamine 6g). Another option is the use of a solid-state narrow-band tunable optical parametric oscillator (OPO) laser, which is also bulky. Further, both approaches require high power class 4 lasers as pumps. Accordingly, the use of such radical monitoring systems can be dangerous due to the high power requirements necessary for their operation. Such laser solutions are also expensive. Due to the size, power requirements, cost, and potential danger, existing solutions for visible laser based on-line monitoring of radicals are difficult to integrate into semiconductor processing tools.

### SUMMARY

Some embodiments described herein relate to an apparatus, that includes a diode laser and a periodically poled lithium niobate (PPLN) waveguide that is coupled to the diode laser by a first optical fiber. In an embodiment, a spectral filter is coupled to the PPLN waveguide by a second optical fiber.

Some embodiments described herein relate to an apparatus that includes a first diode laser, and a first periodically poled lithium niobate (PPLN) waveguide that is coupled to the first diode laser by a first optical fiber. Embodiments may also include a second diode laser, and a second PPLN waveguide that is coupled to the second diode laser by a second optical fiber. In an embodiment, a long pass filter module is coupled to the first PPLN waveguide by a third optical fiber, and the long pass filter module is coupled to the second PPLN waveguide by a fourth optical fiber.

Some embodiments described herein relate to an apparatus that includes a chamber, and a molecular radical detector coupled to the chamber. In an embodiment, the molecular radical detector includes a diode laser, and a periodically poled lithium niobate (PPLN) waveguide coupled to the diode laser by a first optical fiber. In an embodiment, a filter is optically coupled to the PPLN waveguide by a second optical fiber, and a detector is optically coupled to the filter. In an embodiment, the PPLN waveguide is configured to frequency double a beam originating from the diode laser before the beam passes through an optical port in the chamber. In an embodiment, the detector is configured to receive the beam after the beam passes through the chamber.

### BRIEF DESCRIPTION OF THE DRAWINGS

FIG. 1A is schematic illustration of an absorption spectroscopy tool with a diode laser and a periodically poled lithium niobate (PPLN) waveguide that is coupled to a chamber, in accordance with an embodiment.

FIG. 1B is a schematic illustration of an absorption spectroscopy tool with a diode laser and a PPLN waveguide that is coupled to a chamber, in accordance with an additional embodiment.

FIG. 2A is a schematic illustration of an absorption spectroscopy tool with a pair of diode lasers and PPLN waveguides that are coupled to a chamber, in accordance with an embodiment.

FIG. 2B is a schematic illustration of an absorption spectroscopy tool with a pair of diode lasers and PPLN waveguides that are coupled to a chamber, in accordance with an additional embodiment.

FIG. 2C is a schematic illustration of an absorption spectroscopy tool with a pair of diode lasers and PPLN waveguides that are coupled to a chamber, in accordance with an embodiment.

FIG. 3A is a cross-sectional illustration of an absorption spectroscopy tool, in accordance with an embodiment.

FIG. 3B is a plan view illustration of an absorption spectroscopy tool, in accordance with an embodiment.

FIG. 4 is a cross-sectional illustration of a plasma chamber that is monitored with an absorption spectroscopy tool, in accordance with an embodiment.

FIG. 5 is a flow diagram of a process for measuring radicals within a chamber with an absorption spectroscopy tool that comprises a diode laser and a PPLN waveguide, in accordance with an embodiment.

FIG. 6 illustrates a block diagram of an exemplary computer system of a processing tool, in accordance with an embodiment of the present disclosure.

### DETAILED DESCRIPTION

Molecular radical detection within a chamber using a narrow band fiber-coupled near-infrared (IR) laser and a periodically poled lithium niobate (PPLN) waveguide to double the frequency is disclosed herein, in accordance with various embodiments. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, absorption spectroscopy for monitoring radicals in processing chambers is currently limited due to the wavelengths necessary to measure the absorption of desired radicals. For example, many radicals of interest include absorption bands that are in the visible region of the electromagnetic spectrum. However, existing laser sources to provide beams with such bands are limited to continuous wave dye lasers and/or OPO lasers. Both options are expensive, bulky, and dangerous.

Accordingly, embodiments disclosed herein include absorption spectroscopy tools that are based on diode lasers. Diode lasers can be relatively low powered, inexpensive, and compact. As such, absorption spectroscopy tools that incorporate diode lasers are easier to integrate into existing semiconductor processing tools. However, diode lasers have limited commercially available wavelength selections in the visible region and wider selections at near-infrared (IR) wavelengths. These near-IR wavelengths are not typically around the desired wavelengths that correspond to the absorption bands of the targeted radicals. For example, SiH₂ has an absorption band around 580 nm, NH₂ has an absorption band around 600 nm (i.e., 597.4 nm), and CH₂ has an absorption band around 620 nm.

In order to convert the wavelength of the beam generated by the diode laser to a wavelength suitable for detecting the targeted radicals, embodiments disclosed herein provide a periodically poled lithium niobate (PPLN) waveguide that is optically coupled to the diode laser. For example, an optical fiber may be provided between the diode laser and the PPLN waveguide. The photons from the beam originated by the diode laser mix in the PPLN waveguide and generate new photons at the second harmonic of the wavelength of the beam generated by the diode laser. For example, near-IR light at 1,194.8 nm has a second harmonic in the visible region at 597.4 nm, which is suitable for NH₂ detection. The conversion of the beam to the second harmonic may result in a reduction in overall power. However, with an input power of 50 mW to generate the near-IR beam, the resulting second harmonic beam may have an output power of approximately 2 mW, which is still sufficient for providing absorption spectroscopy measurements. While a 50 mW input power may be desirable for some embodiments, a higher input power is also possible. For example, input power up to approximately 500 mW may be used in some embodiments. As used herein, “approximately” may refer to a range within ten percent of the stated value. For example, approximately 500 mW may refer to a range between 450 mW and 550 mW.

In addition to the diode laser and the PPLN waveguide, the absorption spectroscopy tool may also comprise optical components to further improve efficiency of the tool. For example, an optical isolator may be used to prevent reflected photons from passing back through the system. Optical filters may also be used in order to dump portions of the beam that were not fully converted to the second harmonic.

As can be appreciated, the absorption spectroscopy tool may be tuned to measure a particular radical species. However, due to the small size and minimal cost of the components of the absorption spectroscopy tool, a plurality of measurement lines can be integrated into a single tool in order to measure multiple different types radical species. In such an embodiment, the different diode laser and PPLN waveguide pairs may have outputs that are coupled to a filtering module before the beams enter the chamber. The filtering module may comprise a plurality of long pass filters arranged in series. In other embodiments, the measurement lines may be coupled together by a fiber combiner before the filtering module, and a single long pass filter may be used. In the case of a tool with multiple measurement lines, a filter may be used to split the combined beam into individual components after the combined beam passes through the chamber. The split beams may be sent to different detectors in order to measure the absorption of the different radical species. Other spectral filters, such as short pass and bandpass filters, may be used to achieve similar configurations.

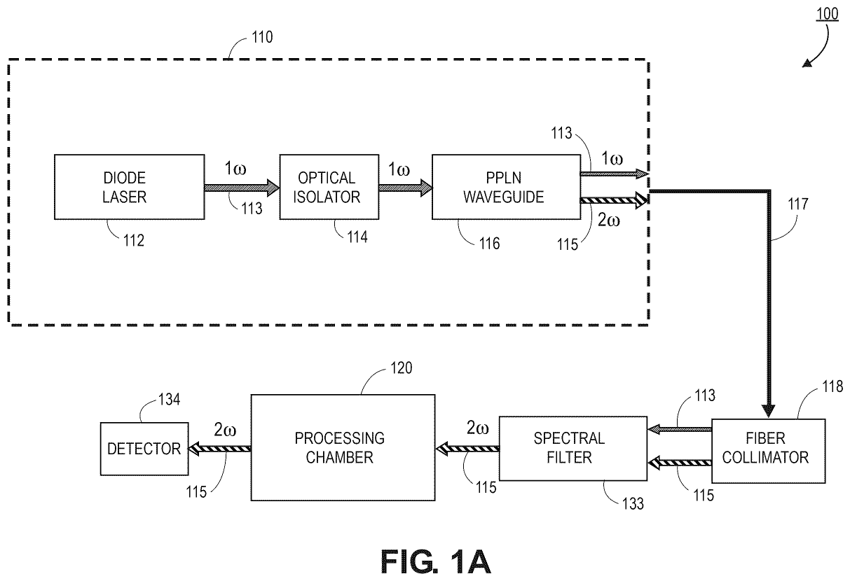

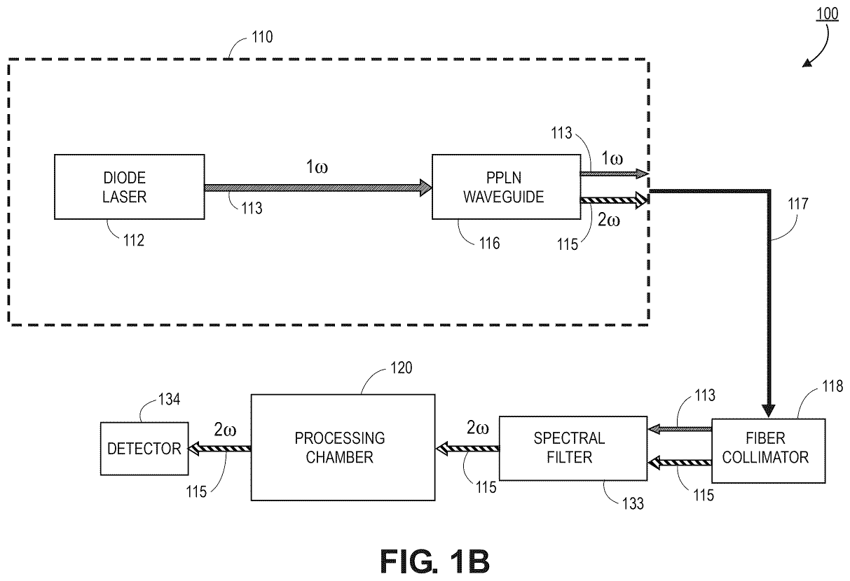

Referring now to FIG. 1A, a schematic illustration of an absorption spectroscopy tool 100 is shown, in accordance with an embodiment. In an embodiment, the absorption spectroscopy tool 100 may comprise a laser module 110. The laser module 110 may comprise a diode laser 112 and a PPLN waveguide 116. The diode laser 112 may comprise any suitable diode laser 112 that provides an output beam 113 at a first wavelength 1ω. The first wavelength 1ω may be a near-IR wavelength. More generally, the first wavelength 1ω may be between approximately 700 nm and approximately 1,600 nm. In a particular embodiment, the first wavelength 1ω may be approximately 1,160 nm, approximately 1,200 nm, or approximately 1,240 nm.

In an embodiment, the PPLN waveguide 116 may be optically coupled to the diode laser 112. For example, an optical fiber may be provided at an output of the diode laser 112, and the optical fiber may couple to an input of the PPLN waveguide 116. In an embodiment, the PPLN waveguide 116 may be configured to generate a converted beam 115 that is at a second harmonic of the output beam 113 from the diode laser 112. For example, the converted beam 115 may have a second wavelength 2ω that is between approximately 350 nm and approximately 800 nm. In a particular embodiment, the second wavelength 2ω may have a wavelength of approximately 580 nm (e.g., for detecting SiH₂ radicals), approximately 600 nm (e.g., for detecting NH₂ radicals), or approximately 620 nm (e.g., for detecting CH₂ radicals). The PPLN waveguide 116 may include any suitable PPLN waveguide structure suitable for providing the second harmonic conversion.

In an embodiment, an optical isolator 114 may be provided within the laser module 110 between the diode laser 112 and the PPLN waveguide 116. The optical isolator 114 ensures that the output beam 113 propagates out towards the PPLN waveguide 116 and the rest of the system without reflecting back into the diode laser 112. Though, as will be described in greater detail below, the optical isolator 114 may be integrated into other parts of the system. In other embodiments, the optical isolator 114 may be integrated into an optical fiber that is provided between the diode laser 112 and the PPLN waveguide 116.

In an embodiment, the laser module 110 may be optically coupled to an optical fiber 117. The optical fiber 117 may be any suitable optical fiber, such as a single mode fiber. In an embodiment, the optical fiber 117 may be coupled to an output of the PPLN waveguide 116. As such, the converted beam 115 may be propagated along the optical fiber 117. Additionally, some portions of the output beam 113 may pass through the PPLN waveguide 116. In such an embodiment, both the converted beam 115 and the output beam 113 may be propagated along the optical fiber 117.

In an embodiment, a second end of the optical fiber 117 may be coupled to a fiber collimator 118. The fiber collimator 118 may collimate the converted beam 115 and the output beam 113. Collimating the converted beam 115 allows for improved efficiency of the system. In an embodiment, the fiber collimator 118 may be optically coupled to a spectral filter 133. The spectral filter 133 may be an optical filter that is configured to remove the original output beam 113 from the system, and the spectral filter 133 may allow for only the converted beam 115 to pass into the processing chamber 120. The spectral filter 133 may be any suitable filter. For example, the spectral filter 133 may be a low pass filter or a bandpass filter.

In an embodiment, the spectral filter 133 may be optically coupled to a chamber 120 by an optical fiber or the like. The converted beam 115 is propagated to the chamber 120, and passes through an interior of the chamber 120 to a detector 134. The detector 134 may be an optical detector used to measure an amount of absorption of the converted beam 115. The amount of absorption can be correlated to the concentration of a particular species within the chamber 120.

In an embodiment, the chamber 120 may be any type of chamber suitable for generating a plasma. In one instance, the chamber 120 is part of a remote plasma system (RPS). In another embodiment, the chamber is the main processing chamber of an etching tool, a deposition tool, a plasma treatment tool, or any other tool suitable for semiconductor processing. The chamber 120 may comprise one or more ports (i.e., optical ports) to allow for the converted beam 115 to pass through a wall of the chamber 120 towards the detector 134.

Referring now to FIG. 1B, a schematic illustration of an absorption spectroscopy tool 100 is shown, in accordance with an additional embodiment. In an embodiment, the absorption spectroscopy tool 100 in FIG. 1B may be similar to the absorption spectroscopy tool 100 in FIG. 1A, with the exception of the laser module 110. Instead of providing a discrete optical isolator 114 between the diode laser 112 and the PPLN waveguide 116, the discrete optical isolator 114 is omitted. In some embodiments, the optical isolator may be integrated into the diode laser 112. Other embodiments may include integrating an optical isolator 114 into one or more of the optical fibers within the absorption spectroscopy tool 100. For example, an optical isolation feature may be integrated into an optical fiber between the diode laser 112 and the PPLN waveguide 116, or an optical isolation feature may be integrated into the optical fiber 117 between the PPLN waveguide 116 and the fiber collimator 118.

In the embodiments described above with respect to FIGS. 1A and 1B, the optical spectroscopy tools 100 include a single diode laser 112. As such, a single radical species can be targeted for measurement. Though, it is to be appreciated that the diode laser 112 and/or the PPLN waveguide 116 may be tuned to have beams within a relatively small range of frequencies (e.g., by actively heating and/or cooling the diode laser 112 and/or the PPLN waveguide 116). However, the differences between absorption bands of different radical species may be too great to allow for tuning from a single diode laser 112.

Accordingly, embodiments disclosed herein may include optical spectroscopy tools 100 that comprise a plurality of measurement lines. Each of the measurement lines may include a laser module that is tuned to measure a particular radical species. Further, it is to be appreciated that the small size of the diode lasers and the PPLN waveguides allows for multiple measurement lines to be integrated into a single tool without a significant increase in the overall footprint of the optical spectroscopy tool. The addition of multiple measurement lines is also a cost effective approach to measuring multiple different types of radical species within a processing chamber.

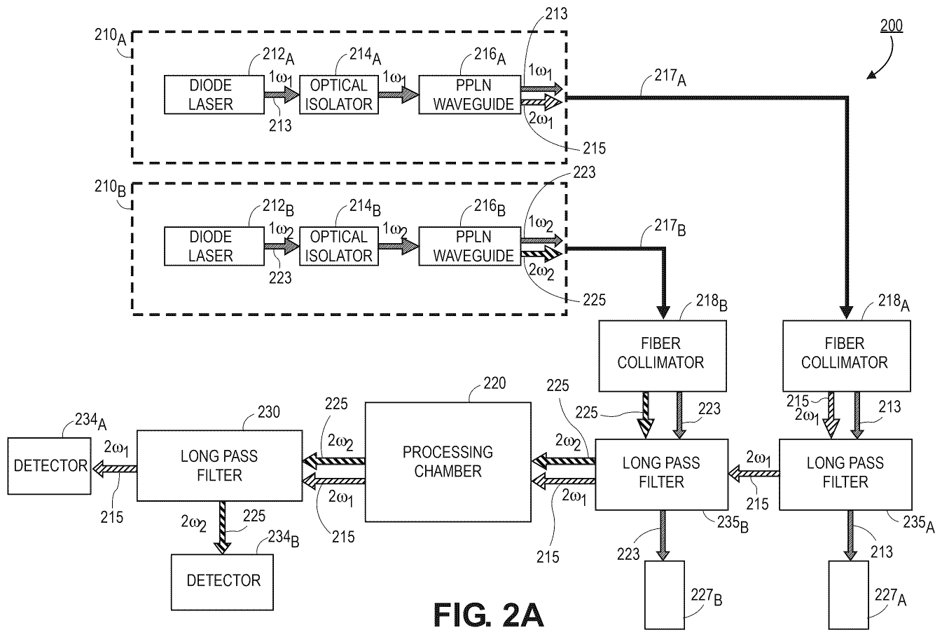

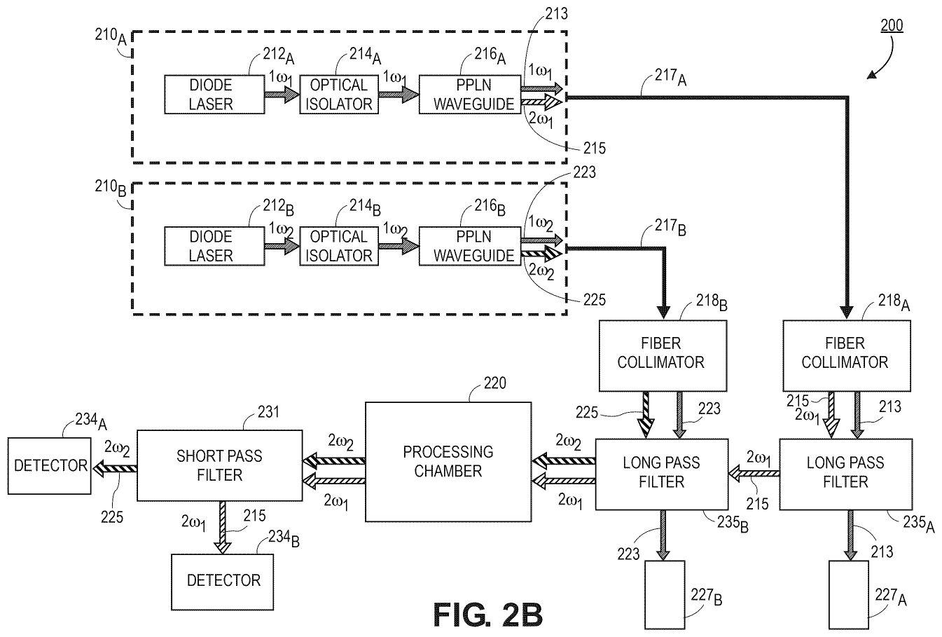

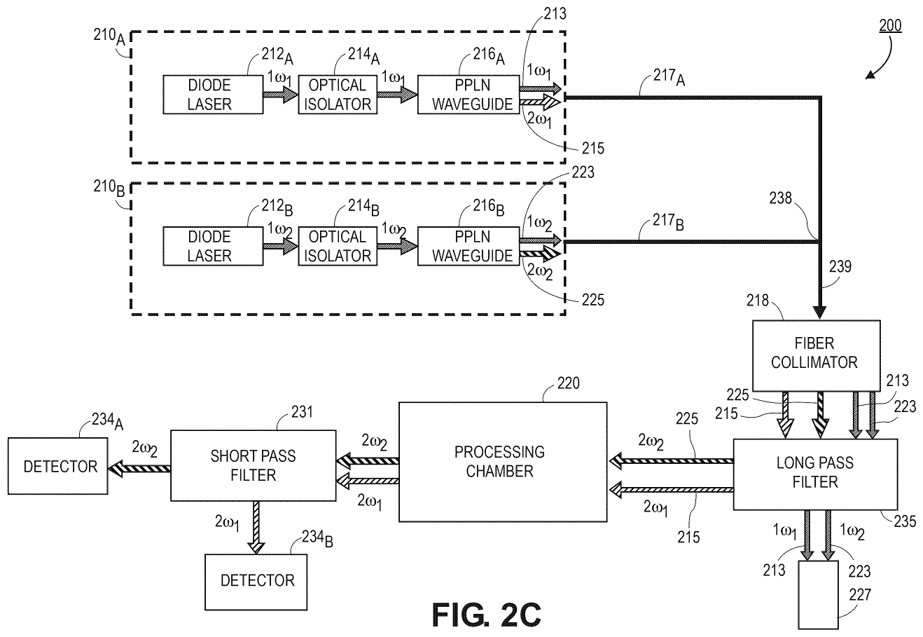

Referring now to FIG. 2A, a schematic illustration of an absorption spectroscopy tool 200 is shown, in accordance with an embodiment. In an embodiment, the absorption spectroscopy tool 200 may comprise a plurality of laser modules 210. For example, a first laser module 210_{A} and a second laser module 210_{B} are shown in FIG. 2A. The laser modules 210 may each comprise a diode laser 212_{A} or 212_{B} and a PPLN waveguide 216_{A} or 216_{B}.

The diode laser 212_{A} may comprise any suitable diode laser that provides an output beam 213 at a first wavelength 1ω₁. The first wavelength 1ω₁ may be a near-IR wavelength. More generally, the first wavelength 1ω₁ may be between approximately 700 nm and approximately 1,600 nm. In a particular embodiment, the first wavelength 1ω₁ may be approximately 1,160 nm, approximately 1,200 nm, or approximately 1,240 nm.

The diode laser 212_{B} may comprise any suitable diode laser that provides an output beam 223 at a first wavelength 1ω₂. The first wavelength 1ω₂ may also be a near-IR wavelength. More generally, the first wavelength 1ω₂ may be between approximately 700 nm and approximately 1,600 nm. In a particular embodiment, the first wavelength 1ω₂ may be approximately 1,160 nm, approximately 1,200 nm, or approximately 1,240 nm. Though, it is to be appreciated that the first wavelength 1ω₁ of the output beam 213 is different than the first wavelength 1ω₂ of the output beam 223. The different wavelengths allow for each of the laser modules 210_{A} and 210_{B} to target different radical species within the chamber 220.

In an embodiment, the PPLN waveguides 216_{A} and 216_{B} may be optically coupled to their respective diode laser 212_{A} or 212_{B}. For example, optical fibers may be provided at an output of the diode lasers 212, and the optical fibers may couple to an input of the PPLN waveguides 216. In an embodiment, the PPLN waveguide 216_{A} may be configured to generate a converted beam 215 that is at a second harmonic of the output beam 213 from the diode laser 212_{A}. For example, the converted beam 215 may have a second wavelength 2ω₁ that is between approximately 350 nm and approximately 800 nm. In a particular embodiment, the second wavelength 2ω₁ may have a wavelength of approximately 580 nm (e.g., for detecting SiH₂ radicals), approximately 600 nm (e.g., for detecting NH₂ radicals), or approximately 620 nm (e.g., for detecting CH₂ radicals).

Similarly, the PPLN waveguide 216; may be configured to generate a converted beam 225 that is at a second harmonic of the output beam 223 from the diode laser 212_{B}. For example, the converted beam 215 may have a second wavelength 2ω₂ that is between approximately 350 nm and approximately 800 nm. In a particular embodiment, the second wavelength 2ω₂ may have a wavelength of approximately 580 nm (e.g., for detecting SiH₂ radicals), approximately 600 nm (e.g., for detecting NH₂ radicals), or approximately 620 nm (e.g., for detecting CH₂ radicals).

In an embodiment, an optical isolator 214A or 214B may be provided within the laser modules 210_{A} or 210_{B} between the diode lasers 212_{A} and 212_{B} and the PPLN waveguides 216_{A} and 216_{B}. The optical isolators 214 ensures that the output beams 213 and 223 propagate out towards the PPLN waveguides 216_{A} and 216_{B} and the rest of the system without reflecting back into the diode lasers 212_{A} and 212_{B}. Though, as described in greater detail herein, the optical isolators 214A and 214B may be integrated into other parts of the system.

In an embodiment, the laser module 210_{A} may be optically coupled to an optical fiber 217A, and the laser module 210_{B} may be optically coupled to an optical fiber 217B. The optical fibers 217 may be any suitable optical fibers, such as single mode fibers. In an embodiment, the optical fibers 217 may be coupled to an output of the PPLN waveguides 216. As such, the converted beam 215 may be propagated along the optical fiber 217A, and the converted beam 225 may be propagated along the optical fiber 217B. Additionally, some portions of the output beam 213 may pass through the PPLN waveguide 216_{A}, and some portions of the output beam 223 may pass through the PPLN waveguide 216_{B}. In such an embodiment, both the converted beam 215 and the output beam 213 may be propagated along the optical fiber 217A, and the converted beam 225 and the output beam 223 may be propagated along the optical fiber 217B.

In an embodiment, second ends of the optical fibers 217A and 217B may be coupled to different fiber collimators 218A and 218B, respectively. The fiber collimators 218 may collimate the converted beams 215 and 225 as well as the output beams 213 and 223. Collimating the converted beams 215 and 225 allows for improved efficiency of the system. In an embodiment, each of the fiber collimators 218 may be optically coupled to a long pass filter 235_{A} or 235_{B}. In an embodiment, the long pass filter 235_{A} and the long pass filter 235_{B} may be arranged in series. That is, an output of the long pass filter 235_{A} may be fed into an input of the long pass filter 235_{B} in some embodiments.

In an embodiment, the long pass filter 235_{A} is configured to send the output beam 213 to a beam dump 227A, and the converted beam 215 is sent to the long pass filter 235_{B}. In an embodiment, the long pass filter 235_{B} takes the output beam 223, the converted beam 225, and the converted beam 215 as inputs. The long pass filter 235_{B} is configured to send the output beam 223 to a beam dump 227B, and the converted beams 215 and 225 are allowed to pass through to the chamber 220. The converted beams 215 and 225 may pass to the chamber 220 along a single optical fiber in some embodiments.

In an embodiment, the converted beams 215 and 225 are propagated to the chamber 220, and pass through an interior of the chamber 220 to a long pass filter 230. The long pass filter 230 may separate the converted beam 215 from the converted beam 225. For example, the converted beam 215 is sent to the detector 234_{A}, and the converted beam 225 is sent to the detector 234_{B}. The detectors 234 may be optical detectors used to measure an amount of absorption of the converted beams 215 or 225. The amount of absorption can be correlated to the concentration of particular species within the chamber 220.

In an embodiment, the chamber 220 may be any type of chamber suitable for generating a plasma. In one instance, the chamber 220 is part of an RPS. In another embodiment, the chamber is the main processing chamber of an etching tool, a deposition tool, a plasma treatment tool, or any other tool suitable for semiconductor processing.

The chamber 220 may comprise one or more ports (i.e., optical ports) to allow for the converted beams 215 and 225 to pass through a wall of the chamber 220 towards the detectors 234_{A} or 234_{B}.

Referring now to FIG. 2B, a schematic illustration of an absorption spectroscopy tool 200 is shown, in accordance with an additional embodiment. As shown, the absorption spectroscopy tool 200 in FIG. 2B is similar to the absorption spectroscopy tool 200 in FIG. 2A, with the exception of the filtering of the converted beams 215 and 225 after passing through the chamber 220. Instead of a long pass filter, a short pass filter 231 is used to separate the converted beam 215 from the converted beam 225. The use of a short pass filter 231 may switch the destination of the converted beam 215 and the converted beam 225. For example, in FIG. 2B the converted beam 215 is sent to the detector 234_{B} and the converted beam 225 is sent to the detector 234_{A}.

Referring now to FIG. 2C, a schematic illustration of an absorption spectroscopy tool 200 is shown, in accordance with an additional embodiment. As shown, the absorption spectroscopy tool 200 in FIG. 2C is similar to the absorption spectroscopy tool 200 in FIG. 2B, with the exception of how the converted beams 215 and 225 are filtered before the chamber 220. Instead of having a filtering module with separate fiber collimators 218 and long pass filters 235, the filtering module comprises a single collimator 218 and a single long pas filter 235.

In such an embodiment, the optical fiber 217A and the optical fiber 217B may be merged into a single optical fiber 239. For example, a fiber combiner 238 or the like can be used in order to merge the beams into a single path. For example, the optical fiber 239 may receive the output beam 213, the converted beam 215, the output beam 223, and the converted beam 225. The collimator 218 may collimate all of the beams before they reach the long pass filter 235. The long pass filter 235 may be designed to dump the output beams 213 and 223 to a beam dump 227, and propagate the converted beams 215 and 225 to the processing chamber 220. Such an embodiment may further reduce complexity of the system while reducing costs and footprint (due to fewer components).

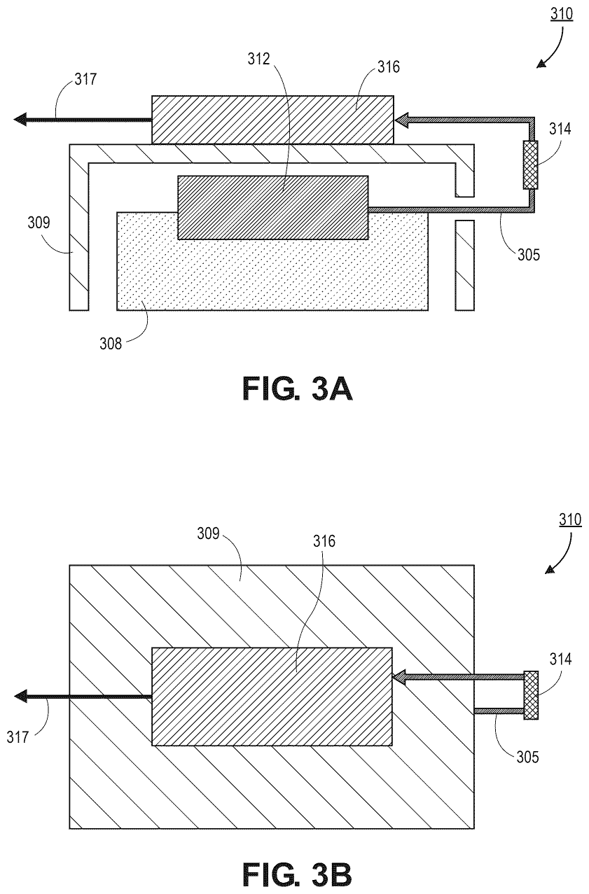

Referring now to FIG. 3A, a cross-sectional illustration of a laser module 310 is shown, in accordance with an embodiment. In an embodiment, the laser module 310 may comprise a housing 309. The housing 309 may surround a diode laser 312. The diode laser 312 may be mounted to a mount 308. The mount 308 may be used to position the diode laser 312. In an embodiment, the mount 308 may also provide temperature control to the diode laser 312 in order to tune the laser module 310. In an embodiment, the diode laser 312 may be similar to any of the diode lasers described in greater detail herein. For example, the diode laser 312 may be a semiconductor based diode laser that emits a beam in the near-IR range.

In an embodiment, an optical fiber 305 may optically couple the diode laser 312 to a PPLN waveguide 316. The optical fiber 305 may also comprise an optical isolator 314, or the optical isolator 314 may be directly integrated into the optical fiber or integrated into the diode laser 312. The optical isolator 314 may be omitted from the laser module 310. For example, an optical isolator may be integrated into other components (not shown) that are coupled to the laser module 310.

In an embodiment, the PPLN waveguide 316 may be configured to convert a beam emitted by the diode laser 312 to a second harmonic. The second harmonic of the converted beam may be suitable for performing absorption spectroscopy in order to measure a particular species within a chamber (not shown). The output of the PPLN waveguide 316 may be coupled to an additional optical fiber 317.

Referring now to FIG. 3B, a plan view illustration of the laser module 310 is shown, in accordance with an embodiment. As shown, the PPLN waveguide 316 may be supported over a top surface of the housing 309. The optical fiber 305 may extend out from an opening in a sidewall of the housing 309 and be routed to the PPLN waveguide 316.

In an embodiment, the laser module 310 may have a relatively small form factor due to the small size of the diode laser 312 and the PPLN waveguide 316. The optical coupling with optical fiber 305 may also allow for a smaller form factor. In one embodiment, a thickness of the laser module 310 may be approximately 5 inches or less. In one embodiment, a footprint of the laser module 310 (e.g., from the left edge of the housing 309 to the right edge of the housing 309 and from the top edge of the housing to the bottom edge of the housing 309 in FIG. 3B) may be approximately 5 inches by 5 inches or smaller.

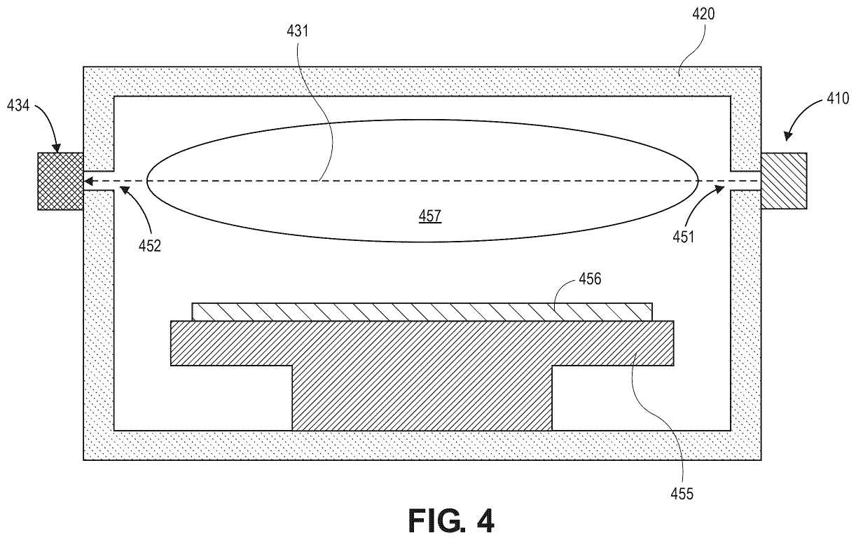

Referring now to FIG. 4, a cross-sectional illustration of a chamber 420 is shown, in accordance with an embodiment. In an embodiment, the chamber 420 may comprise any chamber suitable for supporting a plasma 457. For example, the chamber 420 may be similar to any of the chambers described in greater detail herein. In an embodiment, the chamber 420 may comprise a pedestal 455 for supporting a substrate 456, such as a semiconductor wafer, a panel (e.g., a glass panel, an organic dielectric panel, etc.), or the like. In an embodiment, the chamber 420 may comprise one or more optical ports 451, 452. The optical ports may include windows that are transparent to a beam 431. In an embodiment, the beam 431 may be similar to any of the converted beams described in greater detail herein. For example, the beam 431 may include a wavelength suitable for implementing absorption spectroscopy in order to determine a concentration of radical species within the plasma 457.

In an embodiment, a laser module 410 may be optically coupled to a first optical port 451. The laser module 410 may be similar to any of the laser modules described in greater detail herein. For example, the laser module 410 may comprise a diode laser and a PPLN waveguide (not individually shown). The laser module 410 may be coupled to filtering and/or collimating components similar to any of those described in greater detail herein. In an embodiment, a detector 434 is optically coupled to a second optical port 451. The detector 434 may be similar to any of the detectors described in greater detail herein. In an embodiment, the laser module 410 and the detector 434 may comprise a single measurement line (e.g., similar to the embodiments in FIGS. 1A and 1B), or the laser module 410 and the detector 434 may comprise a plurality of measurement lines (e.g., similar to the embodiments in FIGS. 2A-2C).

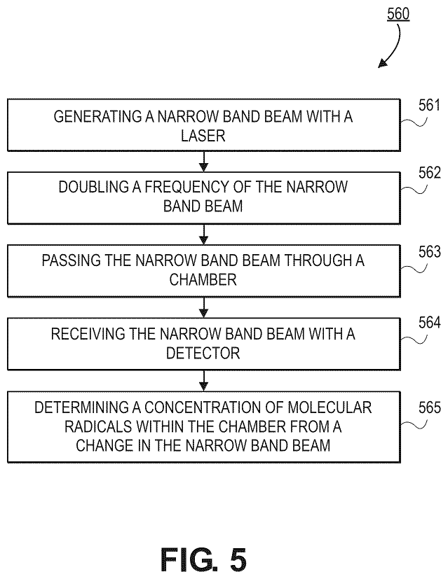

Referring now to FIG. 5, a flow diagram of a process 560 for measuring a radical concentration within a chamber with absorption spectroscopy is shown, in accordance with an embodiment. In an embodiment, the process 560 may begin with operation 561 which comprises generating a narrow band beam with a laser. In an embodiment, the narrow band beam may have a wavelength in the near-IR range. Additionally, the laser may be a diode laser similar to any of the diode lasers described in greater detail herein.

In an embodiment, the process 560 may continue with operation 562, which comprises doubling a frequency of the narrow band beam. In an embodiment, the frequency may be doubled to a second harmonic through the use of a PPLN waveguide. The PPLN waveguide may be similar to any of the PPLN waveguides described in greater detail herein. After the narrow band beam has been converted to a higher frequency, the narrow band beam may be collimated and/or filtered. For example, any un-doubled portion of the narrow band beam may be filtered out.

In an embodiment, the process 560 may continue with operation 563, which comprises passing the narrow band beam through a chamber. In an embodiment, the narrow band beam may pass through a plasma in the chamber. One or more radical species within the plasma may absorb portions of the narrow band beam. Though, in other embodiments, the plasma may be generated in an RPS, and the narrow band beam passes through the chamber downstream of the RPS. In yet another embodiment, the narrow band beam may be passed through the chamber a plurality of times. Passing the narrow band beam may be beneficial to the measurement process. For example, multiple passes of the narrow band beam through the chamber may improve a signal-to-noise ratio of a subsequent measurement.

In an embodiment, the process 560 may continue with operation 564, which comprises receiving the narrow band beam with a detector. The detector may be an optical detector. In an embodiment, the process 560 may continue with operation 565, which comprises determining a concentration of molecular radicals within the chamber from a change in the narrow band beam. For example, a decrease in the intensity of the narrow band beam may represent the presence of molecular radicals that absorb portions of the narrow band beam.

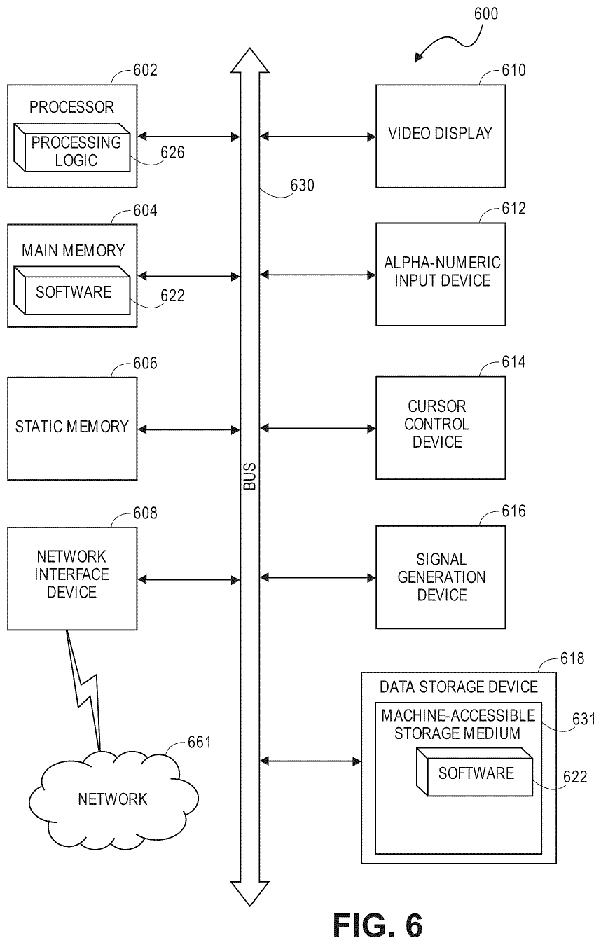

Referring now to FIG. 6, a block diagram of an exemplary computer system 600 of a processing tool is illustrated in accordance with an embodiment. In an embodiment, computer system 600 is coupled to and controls processing in a processing tool suitable for implementing one or more operations for measuring a radical species concentration within a chamber using absorption spectroscopy with a laser module that comprises a diode laser and a PPLN waveguide.

Computer system 600 may be connected (e.g., networked) to other machines in a Local Area Network (LAN), an intranet, an extranet, or the Internet. Computer system 600 may operate in the capacity of a server or a client machine in a client-server network environment, or as a peer machine in a peer-to-peer (or distributed) network environment. Computer system 600 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 600, the term “machine” shall also be taken to include any collection of machines (e.g., computers) that individually or jointly execute a set (or multiple sets) of instructions to perform any one or more of the methodologies described herein.

Computer system 600 may include a computer program product, or software 622, having a non-transitory machine-readable medium having stored thereon instructions, which may be used to program computer system 600 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 600 includes a system processor 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a secondary memory 618 (e.g., a data storage device), which communicate with each other via a bus 630.

System processor 602 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 602 may also be one or more special-purpose processing devices such as an application specific integrated circuit (ASIC), a field programmable gate array (FPGA), a digital signal system processor (DSP), network system processor, or the like. System processor 602 is configured to execute the processing logic 626 for performing the operations described herein.

The computer system 600 may further include a system network interface device 608 for communicating with other devices or machines. The computer system 600 may also include a video display unit 610 (e.g., a liquid crystal display (LCD), a light emitting diode display (LED), or a cathode ray tube (CRT)), an alphanumeric input device 612 (e.g., a keyboard), a cursor control device 614 (e.g., a mouse), and a signal generation device 616 (e.g., a speaker).

The secondary memory 618 may include a machine-accessible storage medium 631 (or more specifically a computer-readable storage medium) on which is stored one or more sets of instructions (e.g., software 622) embodying any one or more of the methodologies or functions described herein. The software 622 may also reside, completely or at least partially, within the main memory 604 and/or within the system processor 602 during execution thereof by the computer system 600, the main memory 604 and the system processor 602 also constituting machine-readable storage media. The software 622 may further be transmitted or received over a network 661 via the system network interface device 608. In an embodiment, the network interface device 608 may operate using RF coupling, optical coupling, acoustic coupling, or inductive coupling.

While the machine-accessible storage medium 631 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

Thus, embodiments of the present disclosure include systems and methods for measuring a radical species concentration within a chamber using absorption spectroscopy with a laser module that comprises a diode laser and a PPLN waveguide.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

What is claimed is:

1. An apparatus, comprising:
a diode laser;
a periodically poled lithium niobate (PPLN) waveguide coupled to the diode laser by a first optical fiber; and
a spectral filter coupled to the PPLN waveguide by a second optical fiber.

2. The apparatus of claim 1, further comprising:
a collimator between the PPLN waveguide and the spectral filter.

3. The apparatus of claim 1, further comprising an optical isolator between the diode laser and the spectral filter.

4. The apparatus of claim 3, wherein the optical isolator is between the PPLN waveguide and the spectral filter.

5. The apparatus of claim 3, wherein the optical isolator is integrated within the second optical fiber.

6. The apparatus of claim 1, wherein the diode laser emits a beam with a wavelength between 700 nm and 1,600 nm.

7. The apparatus of claim 1, wherein the PPLN is configured to double a wavelength of a beam emitted by the diode laser.

8. The apparatus of claim 1, wherein a wavelength of a beam emitted by the spectral filter is approximately 580 nm, approximately 600 nm, or approximately 620 nm.

9. The apparatus of claim 1, wherein the diode laser has an input power of approximately 500 mW or less.

10. The apparatus of claim 1, further comprising:
an optical detector that is optically coupled to an output of the spectral filter.

11. An apparatus, comprising:
a first diode laser;
a first periodically poled lithium niobate (PPLN) waveguide coupled to the first diode laser by a first optical fiber;
a second diode laser;
a second PPLN waveguide coupled to the second diode laser by a second optical fiber; and
a long pass filter module coupled to the first PPLN waveguide by a third optical fiber, and wherein the long pass filter module is coupled to the second PPLN waveguide by a fourth optical fiber.

12. The apparatus of claim 11, wherein the long pass filter module comprises a first long pass filter coupled to the third optical fiber, and a second long pass filter coupled to the fourth optical fiber, and wherein an output of the first long pass filter is coupled to an input of the second long pass filter.

13. The apparatus of claim 11, further comprising:
a fiber combiner to merge the third optical fiber with the fourth optical fiber.

14. The apparatus of claim 13, wherein the long pass filter module comprises a single long pass filter.

15. The apparatus of claim 11, further comprising:
a filter optically coupled to the long pass filter, wherein the filter separates a first beam that originates from the first PPLN waveguide from a second beam that originates from the second PPLN waveguide.

16. The apparatus of claim 15, wherein the filter is a long pass filter or a short pass filter.

17. The apparatus of claim 15, wherein a first output of the filter is optically coupled to a first detector, and wherein a second output of the filter is optically coupled to a second detector.

18. An apparatus, comprising:
a chamber; and
a molecular radical detector coupled to the chamber, wherein the molecular radical detector comprises:
a diode laser;
a periodically poled lithium niobate (PPLN) waveguide coupled to the diode laser by a first optical fiber;
a filter optically coupled to the PPLN waveguide by a second optical fiber; and
a detector optically coupled to the filter, wherein the PPLN waveguide is configured to frequency double a beam originating from the diode laser before the beam passes through an optical port in the chamber, and wherein the detector is configured to receive the beam after the beam passes through the chamber.

19. The apparatus of claim 18, wherein a footprint of a module comprising the diode laser and the PPLN waveguide is less than 5 inches by 5 inches, and wherein a thickness of the module is less than 5 inches.

20. The apparatus of claim 18, wherein the diode laser is a near-infrared (IR) laser.
